(19) United States
(12) Patent Application Publication
(10) Pub. No.: US 2026/0213446 A1
(43) Pub. Date: Jul. 23, 2026

(54) ELECTRONIC DEVICE INCLUDING CONNECTOR SUPPORT STRUCTURE

(71) Applicant: Samsung Electronics Co., Ltd., Suwon-si (KR)

(72) Inventor: Woojung SHIM, Suwon-si (KR)

(21) Appl. No.: 19/564,542

(22) Filed: Mar. 12, 2026

Related U.S. Application Data
(63) Continuation of application No. PCT/KR2024/014304, filed on Sep. 23, 2024.

(30) Foreign Application Priority Data
Sep. 25, 2023 (KR) 10-2023-0128121

(51) Int. Cl. H01R 12/77; H01R 12/79; H05K 5/02

(52) U.S. Cl. CPC H01R 12/771; H01R 12/79; H05K 5/0226

(57) ABSTRACT

An electronic device is provided. The electronic device includes a housing, a substrate disposed in the housing, a receptacle disposed on the substrate and including a first side surface and a second side surface that face each other with a terminal part interposed therebetween, an electrical connection member including a connector connected to the receptacle and a reinforcement member disposed to support the connector, and a support structure disposed around the receptacle on the substrate, wherein the support structure includes a first portion disposed, in the substrate, to correspond to the first side surface and including a first tension rib, and a second portion disposed, in the substrate, to correspond to the second side surface and including a second tension rib, and wherein, when the connector is connected to the receptacle, the reinforcement member is elastically supported by the first tension rib and the second tension rib.

### CROSS-REFERENCE TO RELATED APPLICATION(S

This application is a continuation application, claiming priority under 35 U.S.C. § 365(c), of an International application No. PCT/KR2024/014304, filed on September 23, 2024, which is based on and claims the benefit of a Korean patent application number 10-2023-0128121, filed on September 25, 2023, in the Ministry of Intellectual Property (MOIP), the disclosure of which is incorporated by reference herein in its entirety.

### BACKGROUND

### 1. Field

The disclosure relates to an electronic device including a connector support structure.

### 2. Description of Related Art

The electronic device may include a plurality of electric components. The electric components provided in the electronic device may be arranged to be spaced predetermined intervals apart from each other. Such a spaced arrangement may be required by the design structure of various components in the electronic device, or may be intended to prevent noise generated by each component from degrading the performance of a counterpart component.

In order to electrically connect the at least two electrical components described above, a separate electrical connection member must be provided, and such an electrical connection member may require a design structure that ensures operational reliability even after long-term use of the electronic device or under external impact.

The above information is presented as background information only to assist with an understanding of the disclosure. No determination has been made, and no assertion is made, as to whether any of the above might be applicable as prior art with regard to the disclosure.

### SUMMARY

An electronic device may include an electrical connection member (e.g., an electrical connection device) configured to electrically connect a first electric component (e.g., a first substrate or a main substrate) and a second electric component (e.g., a second substrate or a sub-substrate) that are spaced apart from each other in an internal space. The electrical connection member may include a cable having a predetermined length (e.g., a flexible printed circuit board (FPCB)), and the two electric components may be electrically connected by bringing a connector (e.g., a plug) disposed at an end of the cable and a receptacle (e.g., a socket) disposed in the opposing electric component into physical contact.

The electronic device may include a foldable electronic device including a first housing and a second housing rotatably connected to the first housing via a hinge device (e.g., a hinge structure or a hinge module). The electrical connection member may have one end electrically connected to the first electric component (e.g., the first substrate) disposed in the first housing, and the other end electrically connected to the second electric component (e.g., the second substrate) disposed in the second housing across the hinge device. In such a case, the electrical connection member may electrically connect the first electric component to the second electric component through a connection mechanism of the connector and the receptacle.

The electronic device may also include a rollable electronic device (or a slidable electronic device) including a first housing and a second housing coupled to the first housing to be slidable from the first housing by a designated reciprocating distance. The electrical connection member may be formed to have a structure (e.g., an elastic bending structure) capable of elastically transforming to operatively accommodate a distance change caused by the sliding movement of the first housing and the second housing, and may electrically connect a first electric component (e.g., a first substrate) disposed in the first housing and a second electric component (e.g., a second substrate) disposed in the second housing. In such a case, the electrical connection member may electrically connect the first electric component to the second electric component through a connection mechanism of the connector and the receptacle.

However, the electrical connection member applied to such electronic devices may experience disconnection or loose insertion of a connector coupled to a receptacle due to repetitive operations (e.g., folding or sliding operations) of the electronic devices, resulting in poor connection, which may degrade the reliability of the electronic devices.

In addition, the electrical connection member may include a reinforcement member (stiffener) having a size larger than the connector so as to provide rigidity to the connector and to support the connector for easy assembly.

However, during the work process of connecting the connector to the receptacle, the connector may be covered by the reinforcement member and thus not visible to the naked eye, which may cause an assembly difficulty for a worker, thereby potentially resulting in damage of the connector or the receptacle due to poor connection.

Aspects of the disclosure are to address at least the above-mentioned problems and/or disadvantages and to provide at least the advantages described below. Accordingly, an aspect of the disclosure is to provide an electronic device including a connector support structure that helps reduce disconnection and loose insertion due to frequent operations of the electronic device.

Another aspect of the disclosure is to provide an electronic device including a connector support structure that helps improve the operational reliability of the electronic device.

Another aspect of the disclosure is to provide an electronic device including a connector support structure that provides improved assemblability.

Additional aspects will be set forth in part in the description which follows and, in part, will be apparent from the description, or may be learned by practice of the presented embodiments.

In accordance with an aspect of the disclosure, an electronic device is provided. The electronic device includes a housing, a substrate disposed in the housing, a receptacle disposed on the substrate and including a first side surface and a second side surface that face each other with a terminal part interposed therebetween, an electrical connection member including a connector connected to the receptacle and a reinforcement member disposed to support the connector, and a support structure disposed around the receptacle on the substrate, wherein the support structure includes a first portion disposed, in the substrate, to correspond to the first side surface and including a first tension rib, and a second portion disposed, in the substrate, to correspond to the second side surface and including a second tension rib, and wherein, when the connector is connected to the receptacle, the reinforcement member is elastically supported by the first tension rib and the second tension rib.

In accordance with another aspect of the disclosure, an electronic device is provided. The electronic device includes a first housing including a first substrate having a receptacle disposed thereon, the receptacle including a first side surface and a second side surface facing each other with a terminal part interposed therebetween, a second housing rotatably connected to the first housing through a hinge device and including a second substrate, an electrical connection member including a connector electrically connected from the first substrate to the second substrate through the hinge device and connected to the receptacle, and a reinforcement member disposed to support the connector, and a support structure disposed around the receptacle on the first substrate, wherein the support structure includes a first portion disposed, in the first substrate, to correspond to at least a portion of the first side surface and including a first tension rib, and a second portion disposed, in the first substrate, to correspond to at least a portion of the second side surface and including a second tension rib, and wherein, when the connector is connected to the receptacle, at least a portion of the reinforcement member is elastically supported by at least one of the first tension rib and the second tension rib.

The electronic device according to the embodiments of the disclosure includes a support structure (e.g., a guide and a clip for fixing) that is disposed around the receptacle and supports and guides the reinforcement member (stiffener) at the time of connector connection, and thus, helps improve the reliability of the electronic device by reducing poor connection due to repeated operations (e.g., folding or sliding operations) of the electronic device and also facilitates smooth and fast assembly.

In addition, various other effects that may be directly or indirectly recognized through the disclosure may be provided.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2A is a front perspective view of an electronic device according to an embodiment of the disclosure;

FIG. 2B is a rear perspective view of an electronic device according to an embodiment of the disclosure;

FIG. 3 is a view of an internal structure of an electronic device when viewed from the rear side, according to an embodiment of the disclosure;

FIG. 4A is a view illustrating a state before connection of a receptacle and a connector according to an embodiment of the disclosure;

FIG. 4B is a schematic view of a support structure when viewed in various directions, according to an embodiment of the disclosure;

FIG. 4C is a schematic view of an electrical connection member according to an embodiment of the disclosure;

FIG. 5A is a view illustrating a state in which a connector is connected to a receptacle, according to an embodiment of the disclosure;

FIG. 5B is a cross-sectional view of a portion of a connection structure in which a connector is connected to a receptacle, taken along line 5B-5B in FIG. 5A, according to an embodiment of the disclosure;

FIGS. 6A, 6B, 6C, 6D, and 6E are views illustrating a state in which a reinforcement member is supported by a support structure according to various embodiments of the disclosure;

FIGS. 7A, 7B, 7C, and 7D are views illustrating configurations of support structures according to various embodiments of the disclosure; and

FIG. 8 is a schematic view of an electronic device according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

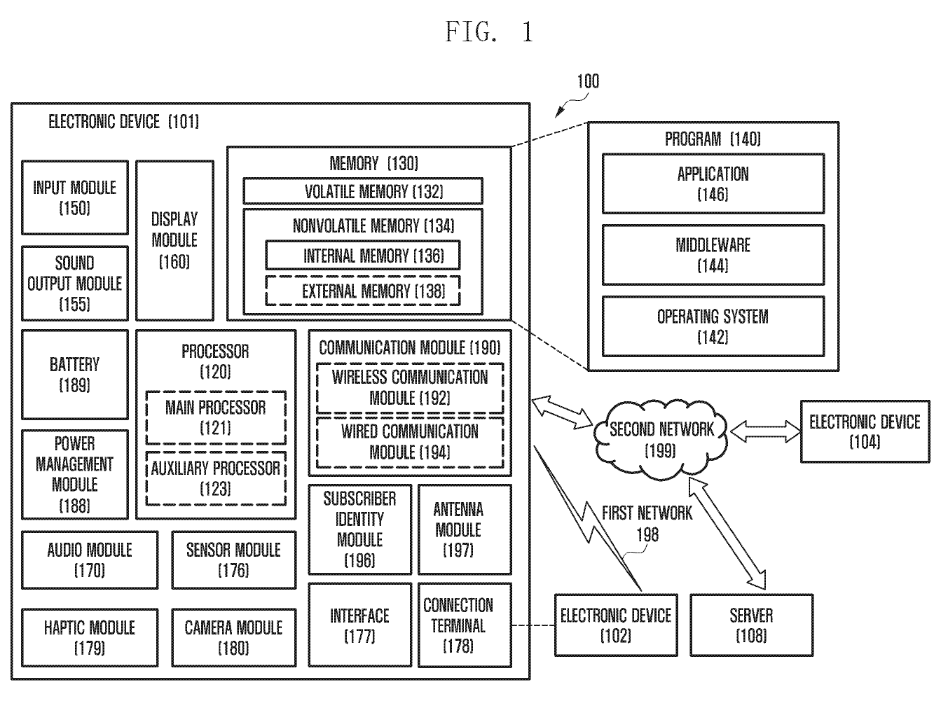

FIG. 1 is a block diagram illustrating an example electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134 (e.g., internal memory 136 or external memory 138).

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as BluetoothTM, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or user plane (U-plane) latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102 or 104, or the server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

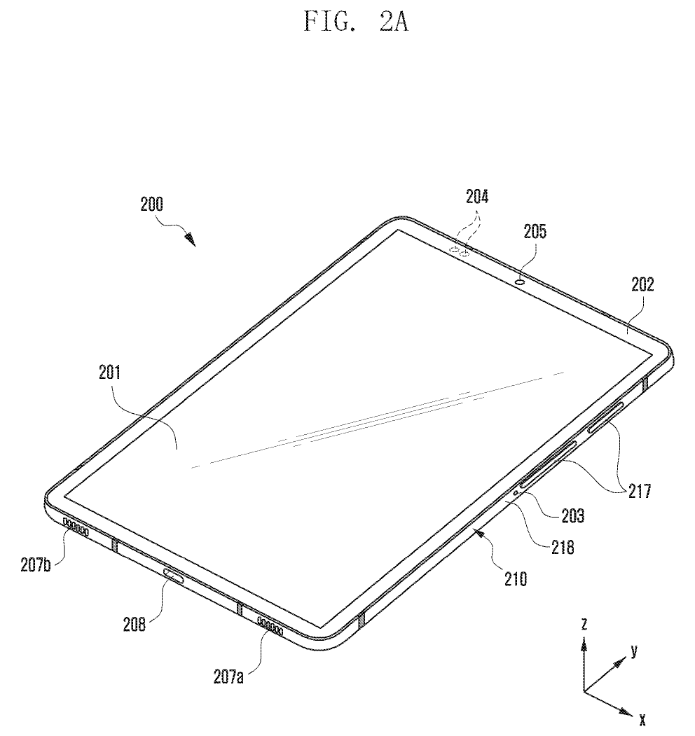

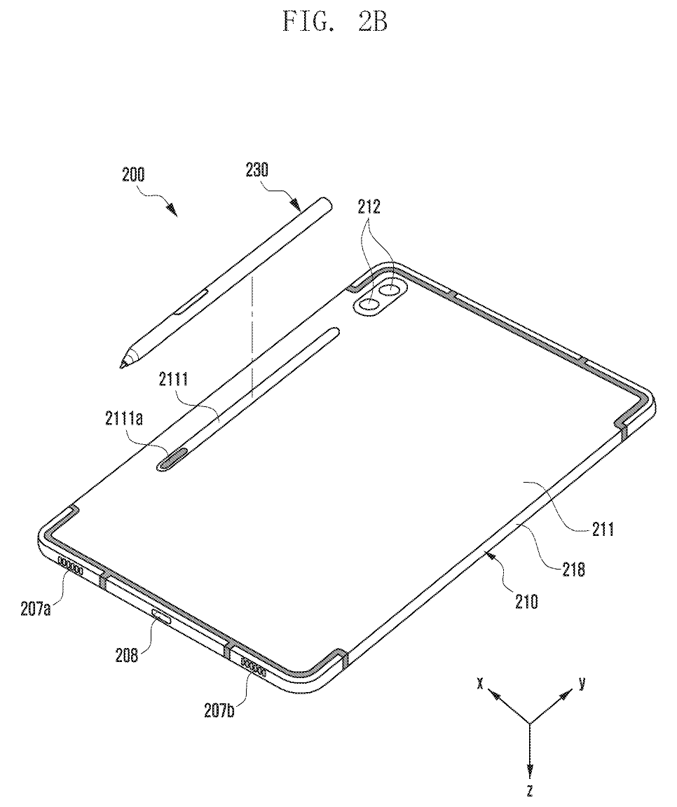

FIG. 2A is a front perspective view of an electronic device according to an embodiment of the disclosure. FIG. 2B is a rear perspective view of an electronic device according to an embodiment of the disclosure.

An electronic device 200 of FIGS. 2A and 2B may be at least partially similar to the electronic device 101 of FIG. 1 or may further include other embodiments of the electronic device.

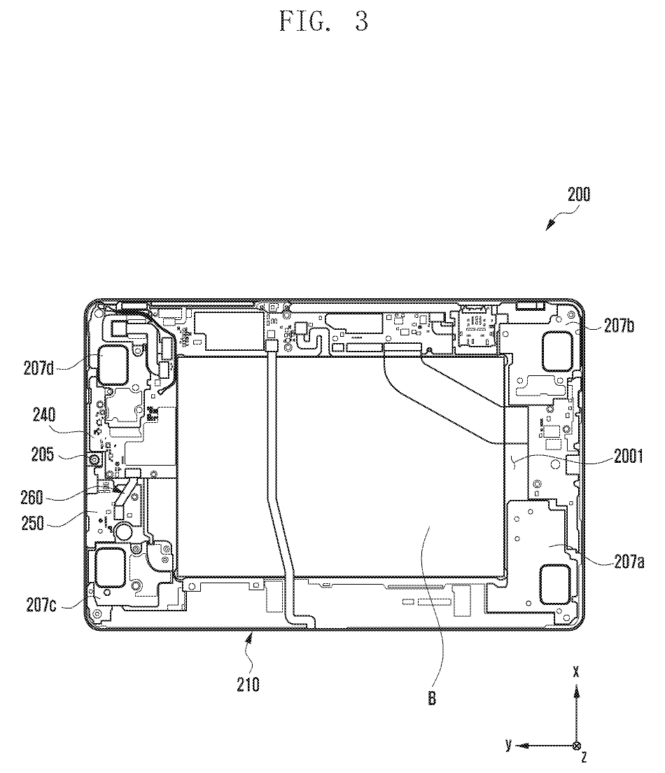

Referring to FIGS. 2A and 2B, the electronic device 200 may include a housing 210 (e.g., a housing structure) that includes a front surface cover 202 facing in a first direction (the z-axis direction), a rear surface cover 211 facing in a direction opposite to the first direction (the -z-axis direction), and a side surface member 218 surrounding an internal space (e.g., the internal space 2001 of FIG. 3) between the front surface cover 202 and the rear surface cover 211. In an embodiment, the front surface cover 202 may be formed of a glass plate including various coating layers, or a polymer plate. In an embodiment, the rear surface cover 211 may be formed, for example, of coated or colored glass, ceramic, polymer, metal (e.g., aluminum, stainless steel (STS), or magnesium), or a combination of at least two of the above materials. In an embodiment, the side surface member 218 may be coupled to the front surface cover 202 and the rear surface cover 211 and may be formed as a side bezel structure including a metal and/or a polymer. In another embodiment, the rear surface cover 211 and the side surface member 218 may be integrally formed and may include the same material (e.g., a metal material such as aluminum or magnesium).

According to various embodiments, the electronic device 200 may include at least one of a display 201, at least one input device 203, sound output devices 207a and 207b, a sensor module 204, camera modules 205 and 212, a key input device 217, and a connector 208. In some embodiments, the electronic device 200 may omit at least one of the above-described elements (e.g., the key input device 217) or may additionally include other elements. In an embodiment, the display 201 may be exposed, for example, through a considerable portion of the front surface cover 202. In another embodiment, the display 201 may be exposed through substantially the entire area of the front surface cover 202. In an embodiment, the display 201 may have a recess or an opening in a portion of a screen display area, and at least one of the above-described elements may be disposed to align with the recess or the opening in the internal space of the electronic device 200. In an embodiment, at least one of the sensor module 204 and the camera module 205 may be disposed on the rear surface of the screen display area (e.g., the active area) of the display 201 in an internal space (e.g., the internal space 2001 of FIG. 3) of the electronic device 200. In an embodiment, the display 201 may be coupled to or disposed adjacent to a touch detection circuit, a pressure sensor capable of measuring the intensity (pressure) of a touch, and/or an electromagnetic induction panel (e.g., a digitizer) for detecting a magnetic field-type electronic pen 230.

According to various embodiments, the input device 203 may include at least one microphone module. In some embodiments, the input device 203 may include a plurality of microphone modules arranged at different positions so as to detect the direction of sound. The sound output devices 207a and 207b (and/or the sound output devices 207c and 207d of FIG. 3) may include a speaker module. The speaker module may include an external speaker and/or a receiver for a call.

According to various embodiments, at least one sensor module 204 may generate an electrical signal or a data value corresponding to an internal operating state of the electronic device 200 or an external environmental state. The at least one sensor module 204 may further include at least one of, for example, a proximity sensor, a fingerprint sensor, a heart rate monitor (HRM) sensor, a gesture sensor, a gyro sensor, a pressure sensor, a magnetic sensor, an acceleration sensor, a grip sensor, a color sensor, an infrared (IR) sensor, a biometric sensor, a temperature sensor, a humidity sensor, or an illuminance sensor.

According to various embodiments, the camera modules 205 and 212 may include a front camera module 205 disposed to be exposed to the outside through the front surface cover 202 of the electronic device 200, and a rear camera module 212 disposed to be exposed to the outside through the rear surface cover 211. In an embodiment, the camera modules 205 and 212 may include one or more lenses, an image sensor, and/or an image signal processor. In an embodiment, at least two rear camera modules 212 may be arranged to be adjacent to each other and may be disposed like a single camera module assembly. For example, the rear camera module assembly may perform a dual camera function for general shooting, wide-angle shooting, or ultra-wide-angle shooting.

According to various embodiments, the electronic device 200 may include an electronic pen 230 (e.g., a stylus pen) that is detachably disposed in a pen seating portion 2111 provided in at least a partial area of the rear surface cover 211. In an embodiment, the electronic pen 230 may be configured to receive power wirelessly through a charging portion 2111a provided in the pen seating portion 2111.

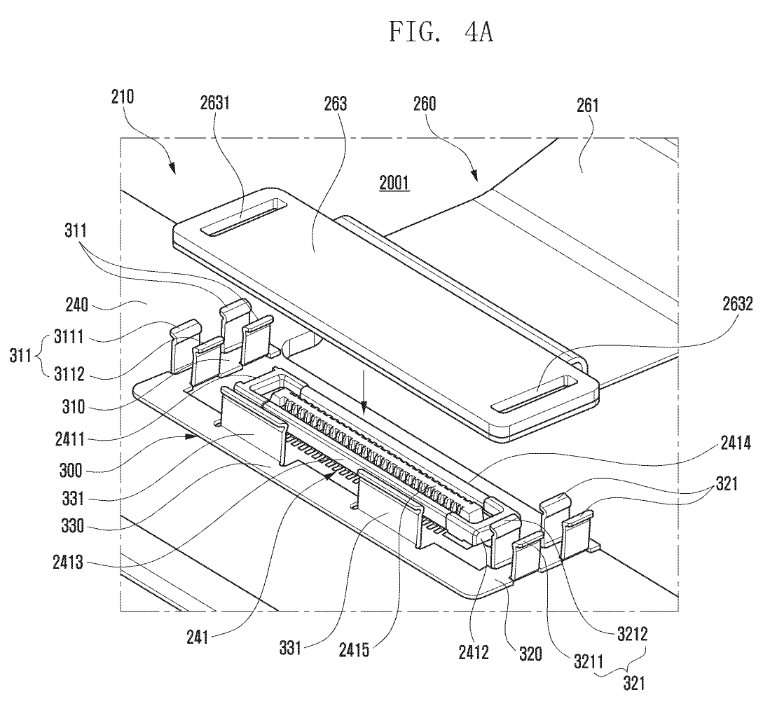

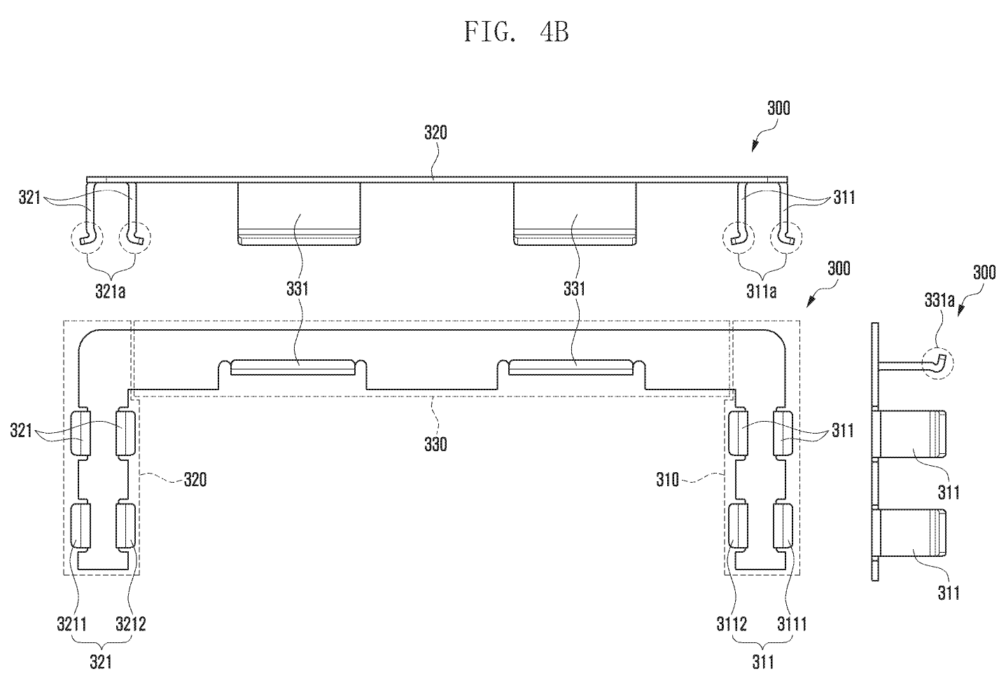

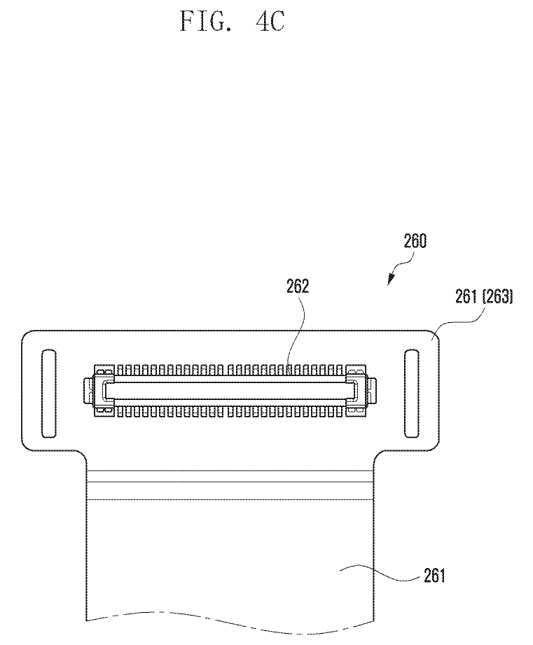

An electronic device 200 according to embodiments of the disclosure may include a connection structure of a receptacle (e.g., the receptacle 241 of FIG. 4A) and a connector (e.g., the connector 262 of FIG. 4C) disposed in an internal space (e.g., the internal space 2001 of FIG. 3). In an embodiment, the electronic device 200 may include a support structure (e.g., the support structure 300 of FIG. 4A) (e.g., a support member or a support structure) configured to guide and support a reinforcement member 263 that is disposed around the receptacle 241 and supports the connector 262. In an embodiment, the connector 262 may be smoothly connected to the receptacle 241 through the guide and support of the reinforcement member 263 by the support structure 300, thereby helping to reduce unintended disassembling or loosening of the connection structure due to external impact.

FIG. 3 is a view of an internal structure of an electronic device when viewed from the rear side, according to an embodiment of the disclosure.

Referring to FIG. 3, an electronic device 200 may include a plurality of electrical components arranged in an internal space 2001 thereof. In an embodiment, the plurality of electrical components may include a battery B, at least one substrate 240 and 250, a camera module 205, or at least one speaker 207a, 207b, 207c, and 207d. In an embodiment, the at least one substrate 240 and 250 may include a first substrate 240 (e.g., a main printed circuit board) and a second substrate 250 (e.g., a sub-printed circuit board) spaced apart from the first substrate 240. In an embodiment, the electronic device 200 may include an electrical connection member 260 disposed to electrically connect the first substrate 240 and the second substrate 250. In an embodiment, the electrical connection member 260 may include a flexible printed circuit board (FPCB) (e.g., the flexible substrate 261 of FIG. 4A). In an embodiment, the electrical connection member 260 may include connectors (e.g., the connector 262 of FIG. 4C) (e.g., a plug) arranged at opposite ends. In an embodiment, the connector 262 may be disposed on the flexible substrate 261 and may be disposed to be fixed to a reinforcement member (stiffener) (e.g., the reinforcement member 263 of FIG. 4A) that provides rigidity. In an embodiment, the electrical connection member 260 may electrically connect the two substrates 240 and 250 in such a manner that the connector 262 disposed to be supported by the reinforcement member 263 is connected to the receptacle (e.g., the receptacle 241 of FIG. 4A) (e.g., a socket) disposed on the first substrate 240 and/or the second substrate 250.

The electronic device 200 according to embodiments of the disclosure may include a support structure (e.g., the support structure 300 of FIG. 4A) disposed around the receptacle 241 on the first substrate 240 and/or the second substrate 250. In an embodiment, the support structure 300 may guide the reinforcement member 263 and support the reinforcement member, thereby guiding the connector 262 to be smoothly connected to the receptacle 241 and helping to reduce poor connection such as loose insertion caused by external impact.

FIG. 4A is a view illustrating a state before connection of a receptacle and a connector according to an embodiment of the disclosure. FIG. 4B is a schematic view of a support structure when viewed in various directions, according to an embodiment of the disclosure. FIG. 4C is a schematic view of an electrical connection member according to an embodiment of the disclosure.

Referring to FIGS. 4A to 4C, an electronic device (e.g., the electronic device 200 of FIG. 3) may include a receptacle 241 disposed on a substrate 240 (e.g., the first substrate 240 of FIG. 3) and including a terminal part 2415 having a plurality of terminals. In an embodiment, the receptacle 241 may include a first side surface 2411, a second side surface 2412 disposed at a position facing the first side surface 2411 with a terminal part 2415 interposed therebetween, a third side surface 2413 configured to connect one end of the first side surface 2411 and one end of the second side surface 2412, and a fourth side surface 2414 configured to connect the other end of the first side surface 2411 and the other end of the second side surface 2412 with the terminal part 2415 interposed therebetween. In an embodiment, the receptacle 241 may be electrically connected to the substrate 240 through a process such as soldering, thereby electrically connecting the plurality of terminals to a plurality of traces of the substrate 240.

According to various embodiments, the electrical connection member 260 may include a flexible substrate 261, a connector 262 electrically connected to an end of the flexible substrate 261, and a reinforcement member (stiffener) 263 that is fixed, in an area of the flexible substrate 261 where the connector 262 is disposed, in such a manner that the reinforcement member is attached thereto while supporting the connector 262. In an embodiment, the reinforcement member 263 may be formed to have a larger size than the connector 262 and may support the connector 262, thereby facilitating connection of the connector 262 to the receptacle 241 or guiding the connector 262 to be easily separated from the receptacle 241. In an embodiment, the reinforcement member 263 may be formed of a metal material or a non-metal material such as polycarbonate (PC) having a predetermined thickness and size.

According to various embodiments, the electronic device (e.g., the electronic device 200 of FIG. 3) may include, on the substrate 240, a support structure 300 disposed around the receptacle 241. In an embodiment, the support structure 300 may be disposed to be attached to the substrate 240 through a process such as soldering. In some embodiments, the support structure 300 may be attached to the substrate 240 through bonding or taping. In an embodiment, the support structure 300 may include a first portion 310 disposed in the vicinity of the first side surface 2411 and disposed to correspond to at least a part of the first side surface 2411 of the receptacle 241 of the receptacle 241, a second portion 320 disposed in the vicinity of the second side surface 2412 and disposed to correspond to at least a part of the second side surface 2412 of the receptacle 241, and a third portion 330 configured to connect the first portion 310 and the second portion 320, disposed in the vicinity of the third side surface 2413, and disposed to correspond to at least a part of the third side surface 2413 of the receptacle 241. In an embodiment, the first portion 310, the second portion 320, and the third portion 330 of the support structure 300 may be integrally formed. In an embodiment, the support structure 300 may be formed of a metal material (e.g., stainless steel).

According to various embodiments, the support structure 300 may include at least one first tension rib 311 protruding upward from the first portion 310. As illustrated, two first tension ribs 311 are arranged on the first portion 310 of the support structure 300, but the disclosure is not limited thereto, and one or three or more first tension ribs may be arranged at a predetermined interval. In an embodiment, at least one first tension rib 311 may include a first sub-tension rib 3111 and a second sub-tension rib 3112 spaced apart from the first sub-tension rib 3111. In an embodiment, the first sub-tension rib 3111 may be disposed to have a predetermined interval in the outward direction from the second sub-tension rib 3112. In an embodiment, the first sub-tension rib 3111 and/or the second sub-tension rib 3112 may include bent portions 311a each having a bent end that is curved, thereby guiding the introduction of the reinforcement member 263 and supporting the introduced reinforcement member 263 to be prevented from being separated. In an embodiment, the bent portions 311a may be formed in such a manner that the bent portions are bent at an end of the first sub-tension rib 3111 and/or the second sub-tension rib 3112 in the outward or inward direction while having a predetermined curvature.

According to various embodiments, the support structure 300 may include at least one second tension rib 321 protruding upward from the second portion 320. In an embodiment, the at least one second tension rib 321 may include a third sub-tension rib 3211 and a fourth sub-tension rib 3212 spaced apart from the third sub-tension rib 3211. In an embodiment, the third sub-tension rib 3211 may be disposed to have a predetermined interval in the outward direction from the fourth sub-tension rib 3212. In an embodiment, the first sub-tension rib 3111 and/or the second sub-tension rib 3112 may also include bent portions 321a each having a bent end that is curved.

According to various embodiments, the support structure 300 may include at least one third tension rib 331 protruding upward from the third portion 330. In an embodiment, the at least one third tension rib 321 may also include a bent portion 331a in which an end portion is curved.

According to various embodiments, the reinforcement member 263 may include a first guide hole 2631 formed at a position corresponding to at least one first tension rib 311, and a second guide hole 2632 formed at a position corresponding to at least one second tension rib 321. In an embodiment, the first guide hole 2631 may be a through-hole through which at least a portion (e.g., the second sub-tension rib 3112) of at least one first tension rib 311 extends when the connector 262 is connected to the receptacle 241. In an embodiment, the second guide hole 2632 may be a through-hole through which at least a portion (e.g., the fourth sub-tension rib 3212) of at least one second tension rib 321 extends when the connector 262 is connected to the receptacle 241.

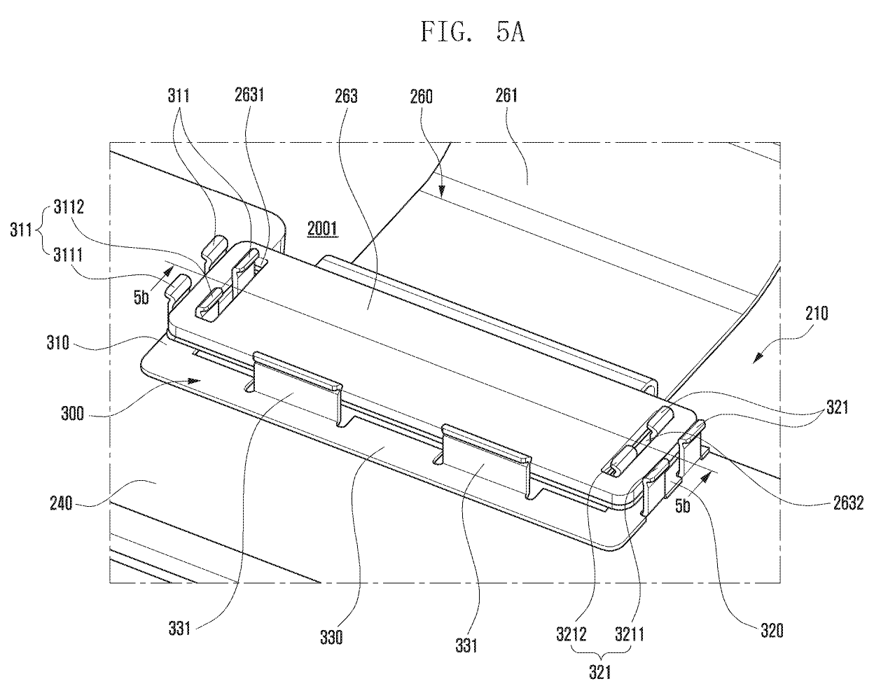

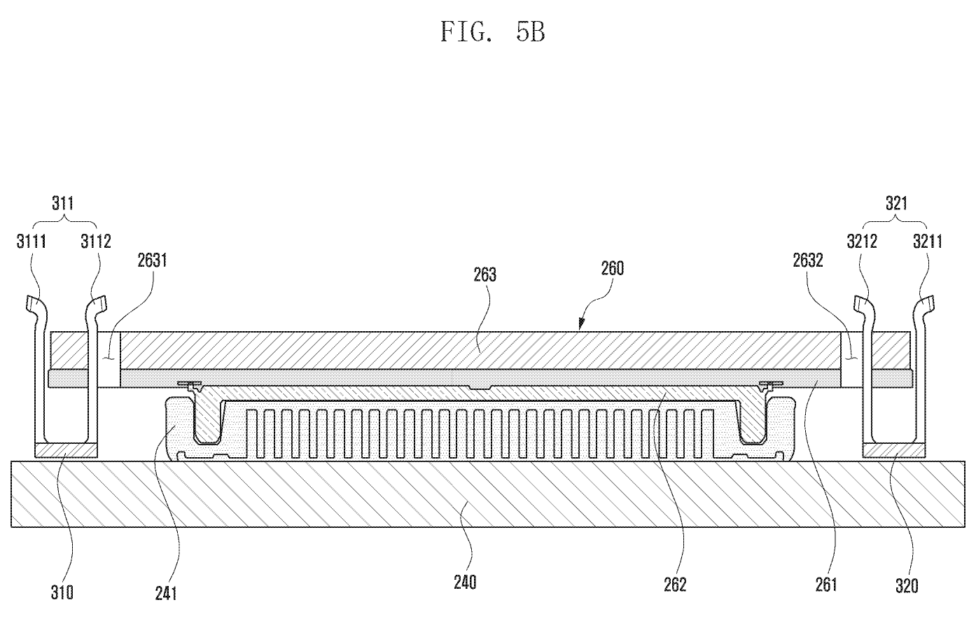

FIG. 5A is a view illustrating a state in which a connector is connected to a receptacle, according to an embodiment of the disclosure. FIG. 5B is a cross-sectional view of a portion of a connection structure in which a connector is connected to a receptacle, taken along line 5B-5B in FIG. 5A, according to an embodiment of the disclosure.

Referring to FIGS. 5A and 5B, an electronic device 200 may include a substrate 240 disposed in an internal space 2001, a receptacle 241 disposed on the substrate 240, and a support structure 300 disposed around the receptacle 241. In an embodiment, when the connector 262 is connected to the receptacle 241, a reinforcement member 263 of an electrical connection member 260 may be disposed to be guided and elastically supported by the support structure 300. In an embodiment, when the connector 262 is connected to the receptacle 241, the reinforcement member 263 may be coupled to the support structure 300 in such a manner that a second sub-tension rib 3112 of at least one first tension rib 311 extends through a first guide hole 2631 of the reinforcement member 263 and a fourth sub-tension rib 3212 of at least one second tension rib 321 extends through a second guide hole 2632 of the reinforcement member 263. For example, a corresponding portion from one end of the reinforcement member 263 to the first guide hole 2631 may be elastically supported and accommodated in a separation space between a first sub-tension rib 3111 and the second sub-tension rib 3112. In an embodiment, a corresponding portion from the other end of the reinforcement member 263 to the second guide hole 2632 may be elastically supported and accommodated in a separation space between a third sub-tension rib 3211 and the fourth sub-tension rib 3212. In an embodiment, the edge area (e.g., a border) between one end and the other end of the reinforcement member 263 may be elastically supported by at least one third tension rib 331.

According to an embodiment of the disclosure, the reinforcement member 263 may be guided to be aligned by the first, second, and third tension ribs 311, 321, and 331 of the support structure 300, and thus, the connector 262 may be correctly connected to the receptacle 241. After being connected, the position of the reinforcement member 263 may be maintained by the elastic support of the tension ribs 311, 321, and 331, which may help reduce poor connection (e.g., disconnection) of the connector 262 due to external impact.

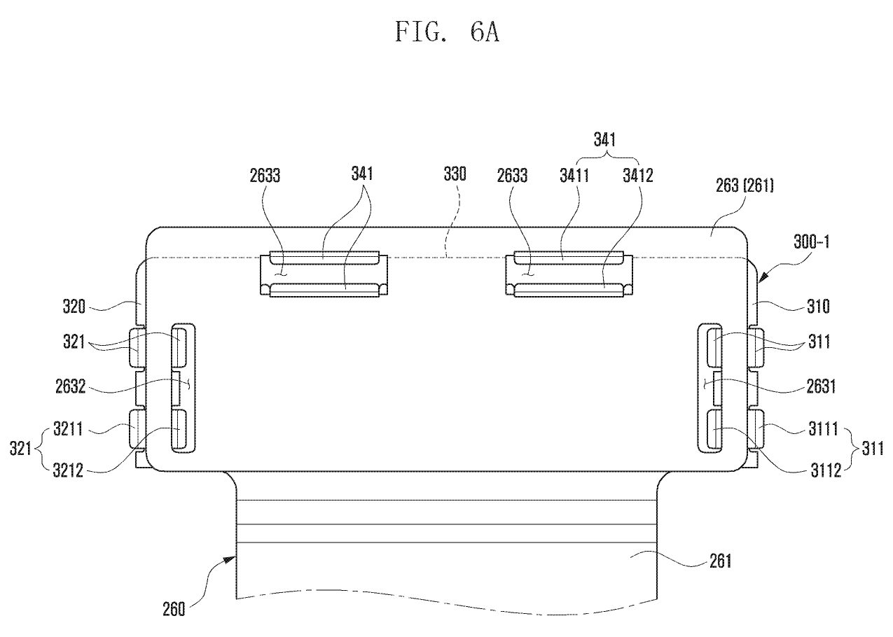

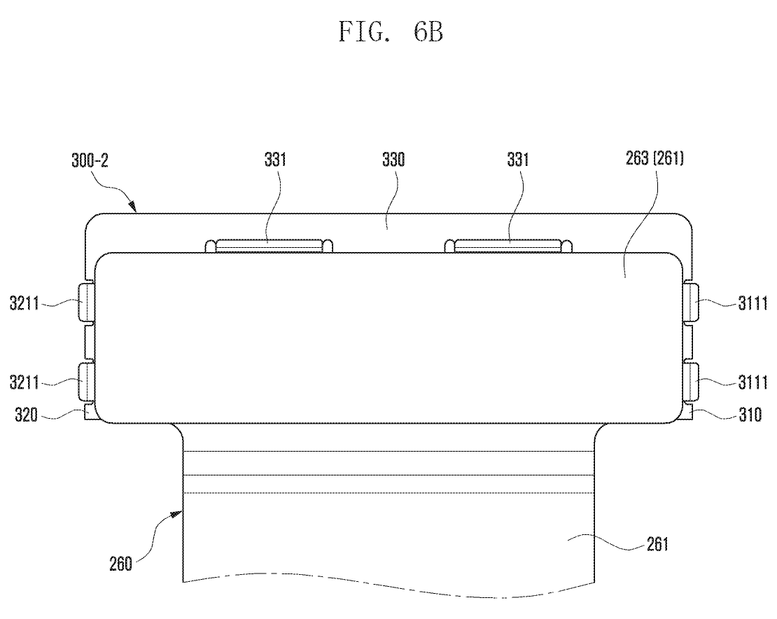

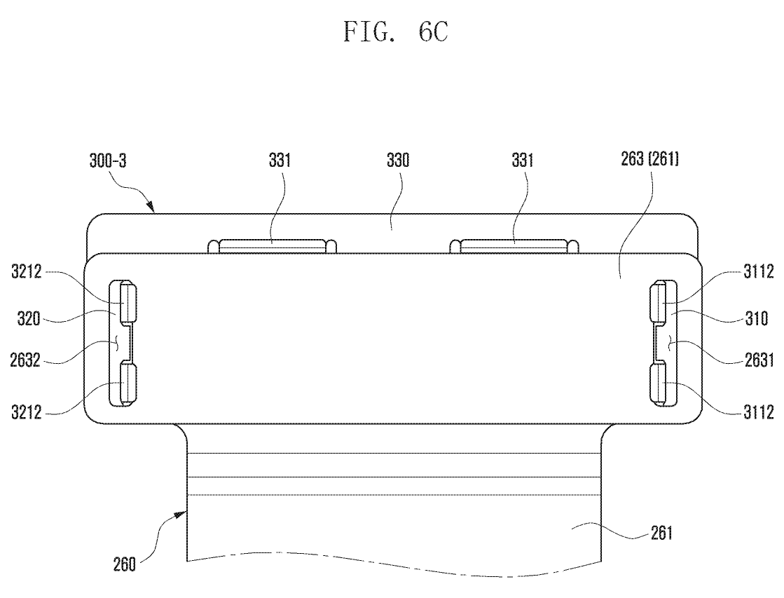

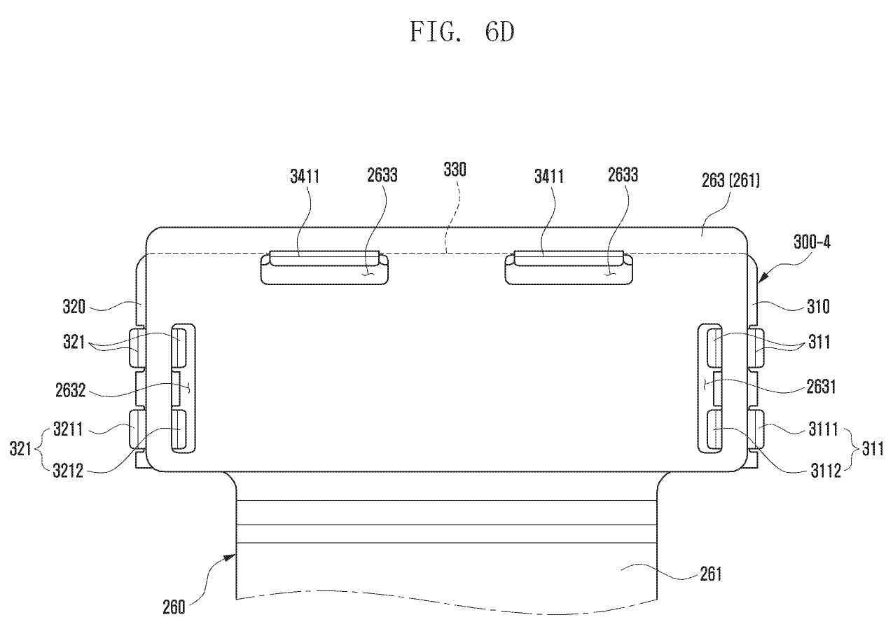

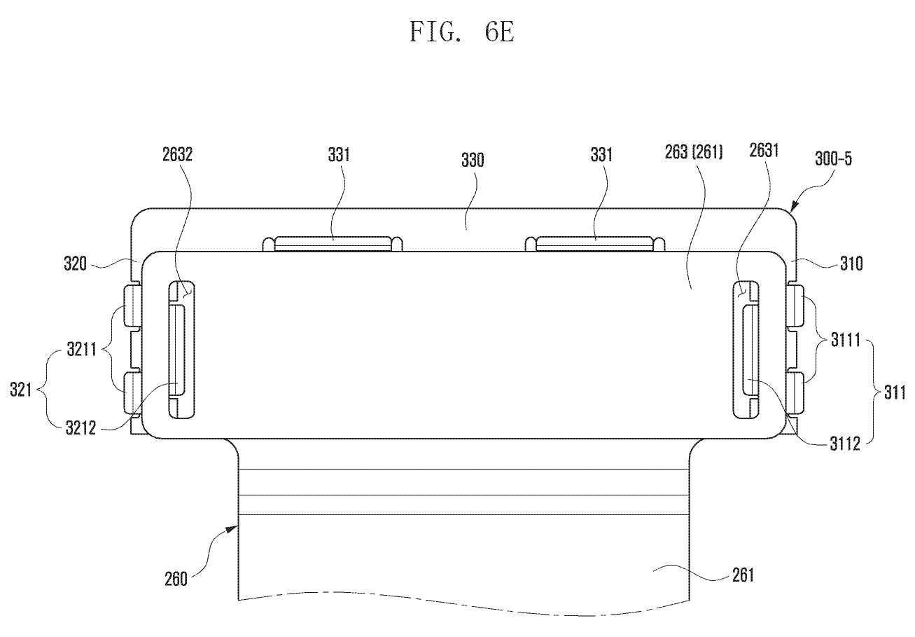

FIGS. 6A, 6B, 6C, 6D, and 6E are views illustrating a state in which a reinforcement member is supported by a support structure according to various embodiments of the disclosure.

In the description of the coupling structure of support structures 300-1, 300-2, 300-3, 300-4, 300-4, and 300-5 and a reinforcement member 263 supported by the support structures in FIGS. 6A to 6E, the same reference numerals may be assigned to components that are substantially the same as the coupling structure of the support structure 300 and the reinforcement member 263 in FIGS. 4A to 4C, and detailed descriptions thereof may be omitted.

Referring to FIG. 6A, the support structure 300-1 may include at least one first tension rib 311 disposed on a first portion 310 and at least one second tension rib 321 disposed on a second portion 320. In an embodiment, the support structure 300-1 may include at least one third tension rib 341 disposed on a third portion 330. In an embodiment, the at least one third tension rib 341 may include fifth sub-tension ribs 3411 and sixth sub-tension ribs 3412 spaced apart from and disposed outwardly from the fifth sub-tension ribs 3411. In an embodiment, the reinforcement member 263 may include a first guide hole 2631 disposed at a position corresponding to at least one first tension rib 311, a second guide hole 2632 disposed at a position corresponding to at least one second tension rib 321, and at least one third guide hole 2633 formed at a position corresponding to at least one third tension rib 341.

According to various embodiments, when the reinforcement member 263 is coupled to the support structure 300-1, a second sub-tension rib 3112 may extend through the first guide hole 2631, a fourth sub-tension rib 3212 may extend through the second guide hole 2632, and a sixth sub-tension rib 3412 may penetrate the third guide hole 2633. For example, the reinforcement member 263 may be disposed to be elastically supported by the first, second, and third tension ribs 311, 321, and 331, each partially extending through the first, second, and third guide holes 2631, 2632, and 2633, respectively.

Referring to FIG. 6B, the support structure 300-2 may include first sub-tension ribs 3111 arranged on the first portion 310, third sub-tension ribs 3211 arranged on the second portion 320, and third tension ribs 331 arranged on the third portion 330. In an embodiment, when the reinforcement member 263 is coupled to the support structure 300-2, an edge (e.g., a border) of the reinforcement member 263 may be disposed to be elastically supported by the first sub-tension ribs 3111, the third sub-tension ribs 3211, and the third tension ribs 331.

Referring to FIG. 6C, the support structure 300-3 may include second sub-tension ribs 3112 arranged on the first portion 310, fourth sub-tension ribs 3212 arranged on the second portion 320, and third tension ribs 331 arranged on the third portion 330. In an embodiment, when the reinforcement member 263 is coupled to the support structure 300-3, the reinforcement member 263 may be disposed to be elastically supported by the second sub-tension ribs 3112 configured to support the reinforcement member 263 after extending through the first guide hole 2631, the fourth sub-tension ribs 3212 configured to support the reinforcement member 263 after extending through the second guide hole 2632, and the third tension ribs 331 configured to support the edge of the reinforcement member 263.

Referring to FIG. 6D, the support structure 300-4 may include at least one tension rib 311 disposed on the first portion 310, at least one second tension rib 321 disposed on the second portion 320, and fifth sub-tension ribs 3411 (e.g., the fifth sub-tension ribs 3411 of FIG. 6A) arranged on the third portion 330. In an embodiment, when the reinforcement member 263 is coupled to the support structure 300-4, the reinforcement member 263 may be disposed to be elastically supported by the at least one first tension rib 311 configured to support the reinforcement member 263 after the second sub-tension ribs 3112 extend through the first guide hole 2631, the at least one second tension rib 321 configured to support the reinforcement member 263 after the fourth sub-tension ribs 3212 extend through the second guide hole 2632, and the fifth sub-tension ribs 3411 configured to support the reinforcement member 263 after extending through the third guide hole 2633.

Referring to FIG. 6E, the support structure 300-5 may include at least one tension rib 311 disposed on the first portion 310, at least one second tension rib 321 disposed on the second portion 320, and one or more third tension ribs 331 (e.g., the third tension rib 331 of FIG. 6B) disposed on the third portion 330. In an embodiment, when the reinforcement member 263 is coupled to the support structure 300-5, the reinforcement member 263 may be disposed to be elastically supported by the at least one first tension rib 311 configured to support the reinforcement member 263 after the second sub-tension rib 3112 extends through the first guide hole 2631, the at least one second tension rib 321 configured to support the reinforcement member 263 after the fourth sub-tension rib 3212 extends through the second guide hole 2632, and the third tension ribs 331 configured to support the edge of the reinforcement member 263. In an embodiment, the second sub-tension rib 3112 may be formed with a size commonly corresponding to the pair of first sub-tension ribs 3111 spaced apart from each other, and the fourth sub-tension rib 3212 may also be formed with a size commonly corresponding to the pair of third sub-tension ribs 3211 spaced apart from each other.

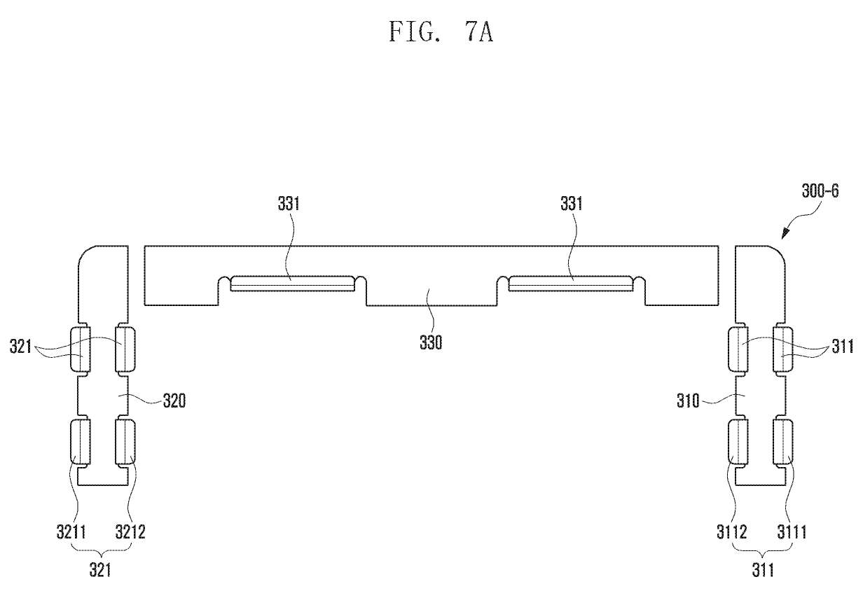

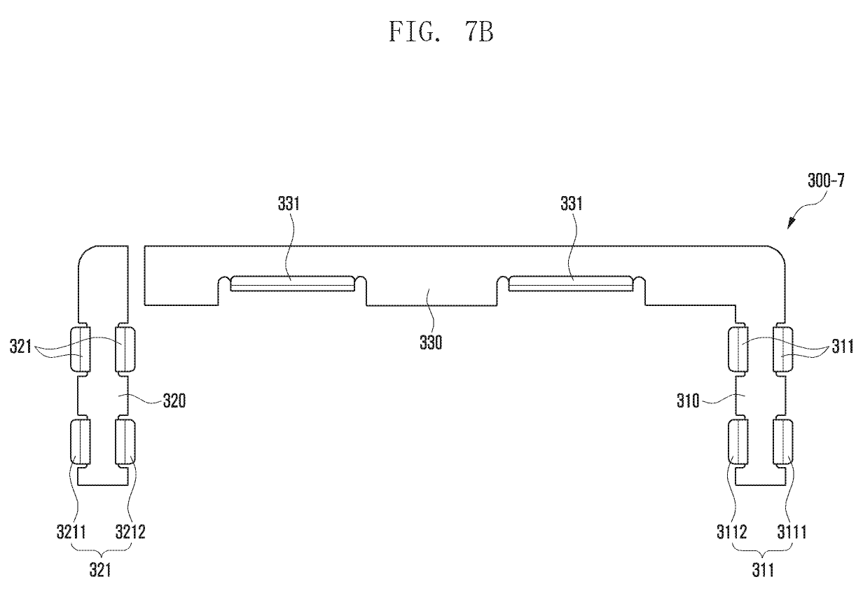

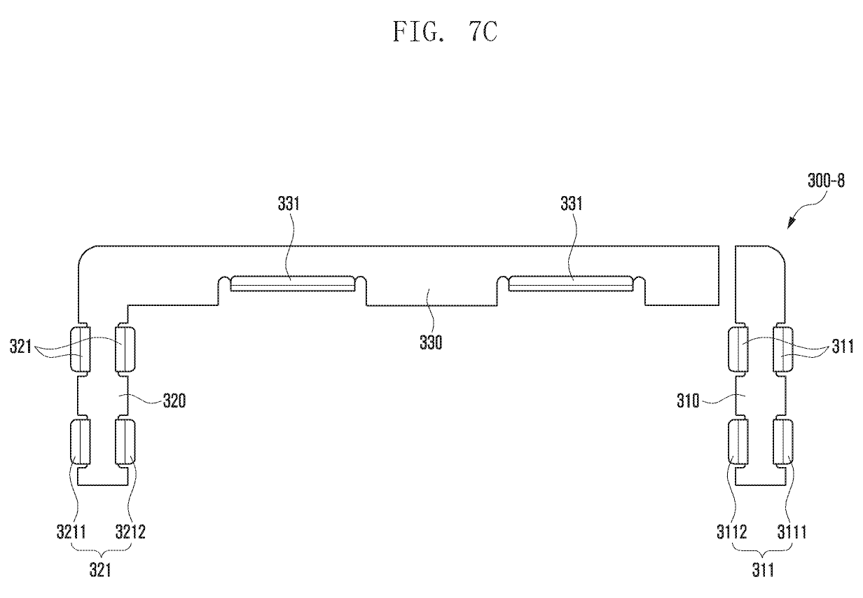

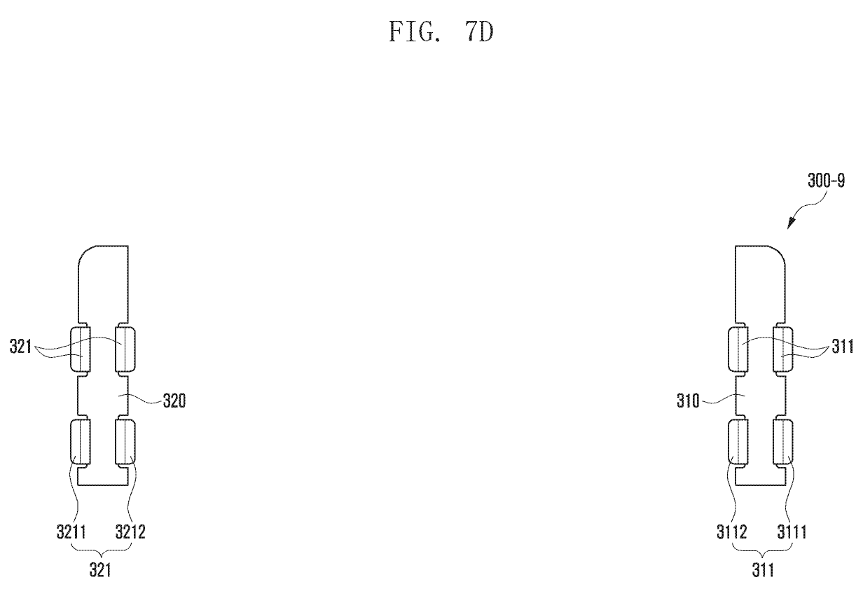

FIGS. 7A, 7B, 7C, and 7D are views illustrating configurations of support structures according to various embodiments of the disclosure.

In the description of support structures 300-6, 300-7, 300-8, and 300-9 of FIGS. 7A to 7D, the same reference numerals may be assigned to components that are substantially the same as the support structure 300 of FIG. 4B, and a detailed description thereof may be omitted.

Referring to FIG. 7A, the support structure 300-6 may include a first portion 310 disposed at a position corresponding to a first side surface 2411 (e.g., the first side surface 2411 of FIG. 4A) of a receptacle (e.g., the receptacle 241 of FIG. 4A) around the first side surface 2411 on a substrate (e.g., the substrate 240 of FIG. 4A), a second portion 320 disposed at a position corresponding to a second side surface 2412 (e.g., the second side surface 2412 of FIG. 4A) of the receptacle around the second side surface 2412, and a third portion 330 disposed at a position corresponding to a third side surface 2413 (e.g., the third side surface 2413 of FIG. 4A) of the receptacle around the third side surface 2413. In an embodiment, the first portion 310 may include at least one first tension rib 311 extending upward. In an embodiment, the second portion 320 may include at least one second tension rib 321 extending upward. In an embodiment, the third portion 330 may include at least one third tension rib 331 extending upward.

The support structure 300-6 according to an embodiment of the disclosure may be disposed in a separated form in which the first portion 310, the second portion 320, and the third portion 330 are spaced apart from each other by a predetermined distance. Such a partially separated arrangement of the support structure 300-6 may be advantageous for maintenance because only the necessary parts can be replaced.

Referring to FIG. 7B, in the support structure 300-7, the first portion 310 and the third portion 330 may be integrally formed, and the second portion 320 may be separately disposed.

Referring to FIG. 7C, in the support structure 300-8, the second portion 320 and the third portion 330 may be integrally formed, and the first portion 310 may be separately disposed.

Referring to FIG. 7D, in the support structure 300-9, the third portion 330 may be omitted, and the first portion 310 and the second portion 320 may be arranged separately.

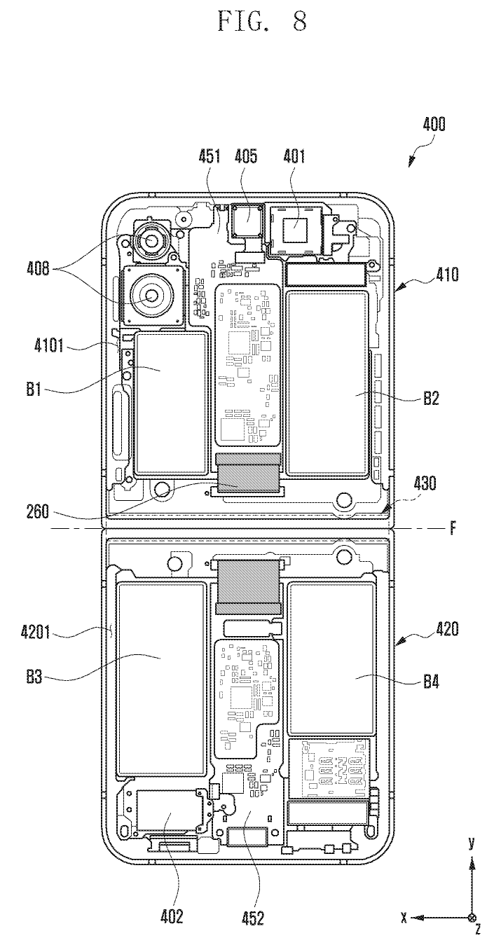

FIG. 8 is a schematic view of an electronic device according to an embodiment of the disclosure.

An electronic device 400 of FIG. 8 may be at least partially similar to the electronic device 101 of FIG. 1 and may further include other embodiments of the electronic device.

Referring to FIG. 8, the electronic device 400 may include a first housing 410, a second housing 420, and a hinge device 430 configured to connect the first housing 410 and the second housing 420 to be foldable about a folding axis F. In an embodiment, the first housing 410, the second housing 420, and the hinge device 430 may be configured as a foldable housing (e.g., a foldable housing structure). In an embodiment, the electronic device 400 may include a plurality of first electrical components arranged in an inner space 4101 of the first housing 410. In an embodiment, the plurality of first electrical components may include batteries B1 and B2, a first substrate 451 disposed between the batteries B1 and B2, and at least one camera module 405 or 408 or speaker module 401 electrically connected to the first substrate 451. In an embodiment, the electronic device 400 may include a plurality of second electrical components arranged in an inner space 4201 of the second housing 420. In an embodiment, the plurality of second electronic components may include batteries B3 and B4, a second substrate 452 disposed between the batteries B3 and B4, and a speaker module 402 electrically connected to the second substrate 452. In an embodiment, the electronic device 400 may include an electrical connection member 260 (e.g., the electrical connection member 260 of FIG. 4A) having one end electrically connected to the first substrate 451 and extending across the hinge device 430 to be electrically connected to the second substrate 452.

The electrical connection member 260 according to an embodiment of the disclosure may include a connector (e.g., the connector 262 of FIG. 4C) supported by a reinforcement member (e.g., the reinforcement member 263 of FIG. 4A). In an embodiment, by being configured to be elastically supported by any one of the support structures (300, 300-1, 300-2, 300-3, 300-4, 300-5, 300-6, 300-7, 300-8, and 300-9) of FIGS. 4A to 4C, 5A, 5B, 6A to 6E, and 7A to 7D described above, the reinforcement member (e.g., the reinforcement member 263 of FIG. 4A) may help reduce poor connection (e.g., loose insertion) of the receptacle (e.g., the receptacle 241 of FIG. 4A) and the connector (e.g., the connector 262 of FIG. 4C), even when the electrical connection member 260 is moved due to repeated folding operations of the electronic device 400.

Although not illustrated, the electronic device may include a second housing that is coupled to the first housing to be slidable from the first housing by a predetermined reciprocating distance. In an embodiment, the electronic device may include an electrical connection member (e.g., the electrical connection member 260 in FIG. 4A) that extends from the first housing to the second housing and has a bent shape elastically deformable to accommodate the sliding movement distance. In an embodiment, the electrical connection member may also have substantially the same structure as the coupling structure of the above-described reinforcement member (e.g., the reinforcement member 263 of FIG. 4A) and the support structure (e.g., the support structures 300, 300-1, 300-2, 300-3, 300-4, 300-5, 300-6, 300-7, 300-8, and 300-9 of FIGS. 4A to 4C, 5A, 5B, 6A to 6E, and 7A to 7D), thereby helping reduce poor connection (e.g., loose insertion) between the receptacle (e.g., the receptacle 241 of FIG. 4A) and the connector (e.g., the connector 262 of FIG. 4C) even when the electrical connection member is moved due to repeated sliding operations.

According to various embodiments, an electronic device (e.g., the electronic device 200 of FIG. 3) may include a housing (e.g., the housing 210 of FIG. 3), a substrate (e.g., the substrate 240 of FIG. 4A) disposed in the housing, a receptacle (e.g., the receptacle 241 of FIG. 4A) disposed on the substrate and having a first side surface (e.g., the first side surface 2411 of FIG. 4A) and a second side surface (e.g., the second side surface 2412 of FIG. 4A) that face each other with a terminal part (e.g., the terminal part 2415 of FIG. 4A) interposed therebetween, an electrical connection member (e.g., the electrical connection member 260 of FIG. 4A) including a connector (e.g., the connector 262 of FIG. 4C) connected to the receptacle and a reinforcement member (stiffener) (e.g., the reinforcement member 263 of FIG. 4A) disposed to support the connector, and a support structure (e.g., the support structure 300 of FIG. 4A) disposed around the receptacle on the substrate, wherein the support structure includes a first portion (e.g., the first portion 310 of FIG. 4B) disposed, in the substrate, to correspond to the first side surface and including a first tension rib (e.g., the first tension rib 311 of FIG. 4B), and a second portion (e.g., the second portion 320 of FIG. 4B) disposed, in the substrate, to correspond to the second side surface and including a second tension rib (e.g., the second tension rib 321 of FIG. 4A), and when the connector is connected to the receptacle, the reinforcement member is elastically supported by the first tension rib and the second tension rib.

According to various embodiments, the reinforcement member may include at least one guide hole (e.g., the first guide hole 2631 and/or the second guide hole 2632 of FIG. 4A), and when the connector is connected to the receptacle, the reinforcement member may be disposed to be supported in such a manner that at least one of the first tension rib or the second tension rib extends through the guide hole.

According to various embodiments, at least one of the first and second tension ribs may include a first sub-tension rib (e.g., the first sub-tension rib 3111 of FIG. 4A) and a second sub-tension rib (e.g., the second sub-tension rib 3112 of FIG. 4A) spaced apart from the first sub-tension rib, wherein the reinforcement member may include at least one guide hole (e.g., the first guide hole 2631 of FIG. 4A), and when the connector is connected to the receptacle, the reinforcement member is disposed to be supported in such a manner that the first sub-tension rib extends through the at least one guide hole.

According to various embodiments, when the connector is connected to the receptacle, the reinforcement member may be disposed such that an edge of the reinforcement member is supported by at least one of the first and second tension ribs.

According to various embodiments, when the connector is connected to the receptacle, at least one of the first and second tension ribs (e.g., the first tension rib 311 and the second tension rib 321 of FIG. 4C) may include curved bent portions (e.g., the bent portions 311a and 321a of FIG. 4C) for guiding the introduction of the reinforcement member.

According to various embodiments, the receptacle may include a third side surface (e.g., the third side surface 2413 of FIG. 4A) connecting the first side surface and the second side surface, and the support structure may include a third portion (e.g., the third portion 330 of FIG. 4B) that is disposed, in the substrate, to correspond to at least a portion of the third side surface and includes a third tension rib (e.g., the third tension rib 331 of FIG. 4A).

According to various embodiments, when the connector is connected to the receptacle, the reinforcement member may be disposed to be supported by at least a portion of the third tension rib.

According to various embodiments, the first and third portions, the second and third portions, or the first, second, and third portions may be integrally formed.

According to various embodiments, the housing may include a first housing (e.g., the first housing 410 of FIG. 8) and a second housing (e.g., the second housing 420 of FIG. 8) rotatably connected to the first housing through a hinge device (e.g., the hinge device 430 of FIG. 8), and the electrical connection member (e.g., the electrical connection member 260 of FIG. 8) may extend from the first housing, across the hinge device, to the second housing.

According to various embodiments, the substrate may include a first substrate (e.g., the first substrate 240 of FIG. 3) disposed in the housing and a second substrate (e.g., the second substrate 250 of FIG. 3) spaced apart from the first substrate, and the electrical connection member may be disposed to electrically connect the first substrate and the second substrate.

According to various embodiments, the housing may include a first housing and a second housing coupled to the first housing to be slidable from the first housing by a predetermined reciprocating distance, and the electrical connection member may extend from the first housing to the second housing.

According to various embodiments, the electrical connection member may include a flexible substrate electrically connected to the connector, and the flexible substrate may be formed in a curved structure elastically deformable to accommodate a movement distance according to the sliding operation of the second housing.

According to various embodiments, the electrical connection member may include a flexible substrate 261, the reinforcement member may be attached to opposite ends of the flexible substrate, and the connector may be electrically connected to opposite ends of the flexible substrate to be supported by the reinforcement member.

According to various embodiments, the support structure may be formed of a metal material.

According to various embodiments, the electronic device may include a first housing (e.g., the first housing 410 of FIG. 8) including a first substrate (e.g., the first substrate 451 of FIG. 8) having a receptacle (e.g., the receptacle 241 of FIG. 4A) including a first side surface (e.g., the first side surface 2411 of FIG. 4A) and a second side surface (e.g., the second side surface 2412 of FIG. 4A) facing each other with a terminal part (e.g., the terminal part 2415 of FIG. 4A) interposed therebetween, a second housing (e.g., the second housing 420 of FIG. 8) rotatably connected to the first housing (e.g., the first housing 410 of FIG. 4A) through a hinge device (e.g., the hinge device 430 of FIG. 8) and including a second substrate (e.g., the second substrate 452 of FIG. 4A), an electrical connection member (e.g., the electrical connection member 260 of FIG. 8) including a connector (e.g., the connector 262 of FIG. 4C) electrically connected from the first substrate to the second substrate through the hinge device and connected to the receptacle, and a reinforcement member (e.g., the reinforcement member 263 of FIG. 4A) disposed to support the connector, and a support structure (e.g., the support structure 300 of FIG. 4A) disposed around the receptacle on the first substrate, wherein the support structure includes a first portion (e.g., the first portion 310 of FIG. 4B) disposed, in the first substrate, to correspond to at least a portion of the first side surface and including a first tension rib (e.g., the first tension rib 311 of FIG. 4A), and a second portion (e.g., the second portion 320 of FIG. 4B) disposed, in the substrate, to correspond to at least a portion of the second side surface and including a second tension rib (e.g., the second tension rib 321 of FIG. 4A), and when the connector is connected to the receptacle, at least a portion of the reinforcement member is elastically supported by at least one of the first tension rib and the second tension rib.

According to various embodiments, the reinforcement member may include at least one guide hole (e.g., the first guide hole 2631 and/or the second guide hole 2632 of FIG. 4A), and when the connector is connected to the receptacle, the reinforcement member may be disposed to be supported in such a manner that at least one of the first tension rib or the second tension rib extends through the guide hole.

According to various embodiments, at least one of the first and second tension ribs may include a first sub-tension rib (e.g., the first sub-tension rib 3111 of FIG. 4A) and a second sub-tension rib (e.g., the second sub-tension rib 3112 of FIG. 4A) spaced apart from the first sub-tension rib, the reinforcement member may include at least one guide hole, and when the connector is connected to the receptacle, the reinforcement member may be disposed to be supported in such a manner that the first sub-tension rib extends through the guide hole.

According to various embodiments, when the connector is connected to the receptacle, the reinforcement member may be disposed such that an edge of the reinforcement member is supported by at least one of the first and second tension ribs.

According to various embodiments, the receptacle may include a third side surface (e.g., the third side surface 2413 of FIG. 4A) connecting the first side surface and the second side surface, and the support structure may include a third portion (e.g., the third portion 330 of FIG. 4B) disposed, in the first substrate, to correspond to at least a portion of the third side surface and including a third tension rib (e.g., the third tension rib 331 of FIG. 4A).

According to various embodiments, when the connector is connected to the receptacle, the reinforcement member may be disposed to be supported by at least a portion of the third tension rib.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a housing;
a substrate disposed in the housing;
a receptacle disposed on the substrate and comprising a first side surface and a second side surface that face each other with a terminal part interposed therebetween;
an electrical connection member comprising a connector connected to the receptacle and a reinforcement member disposed to support the connector; and
a support structure disposed around the receptacle on the substrate,
wherein the support structure comprises:
a first portion disposed, in the substrate, to correspond to the first side surface and comprising a first tension rib; and
a second portion disposed, in the substrate, to correspond to the second side surface and comprising a second tension rib, and
wherein, when the connector is connected to the receptacle, the reinforcement member is elastically supported by the first tension rib and the second tension rib.

2. The electronic device of claim 1,
wherein the reinforcement member comprises at least one guide hole, and
wherein, when the connector is connected to the receptacle, the reinforcement member is disposed to be supported in such a manner that at least one of the first tension rib or the second tension rib extends through the at least one guide hole.

3. The electronic device of claim 1,
wherein at least one of the first and second tension ribs comprises a first sub-tension rib and a second sub-tension rib spaced apart from the first sub-tension rib,
wherein the reinforcement member comprises at least one guide hole, and
wherein, when the connector is connected to the receptacle, the reinforcement member is disposed to be supported in such a manner that the first sub-tension rib extends through the at least one guide hole.

4. The electronic device of claim 1, wherein, when the connector is connected to the receptacle, the reinforcement member is disposed such that an edge of the reinforcement member is supported by at least one of the first and second tension ribs.

5. The electronic device of claim 1, wherein, when the connector is connected to the receptacle, at least one of the first and second tension ribs comprises curved bent portions for guiding an introduction of the reinforcement member.

6. The electronic device of claim 1,
wherein the receptacle comprises a third side surface connecting the first side surface and the second side surface, and
wherein the support structure comprises a third portion disposed, in the substrate, to correspond to at least a portion of the third side surface and comprising a third tension rib.

7. The electronic device of claim 6, wherein, when the connector is connected to the receptacle, the reinforcement member is disposed to be supported by at least a portion of the third tension rib.

8. The electronic device of claim 6, wherein the first and third portions, the second and third portions, or the first, second, and third portions are integrally formed.

9. The electronic device of claim 1,
wherein the housing comprises:
a first housing; and
a second housing rotatably connected to the first housing through a hinge device, and
wherein the electrical connection member extends from the first housing, across the hinge device, to the second housing.

10. The electronic device of claim 1,
wherein the substrate comprises a first substrate disposed in the housing and a second substrate spaced apart from the first substrate, and
wherein the electrical connection member is disposed to electrically connect the first substrate and the second substrate.

11. The electronic device of claim 1,
wherein the housing comprises:
a first housing; and
a second housing coupled to the first housing to be slidable from the first housing by a predetermined reciprocating distance, and
wherein the electrical connection member extends from the first housing to the second housing.

12. The electronic device of claim 11,
wherein the electrical connection member comprises a flexible substrate electrically connected to the connector, and
wherein the flexible substrate is formed in a curved structure elastically deformable to accommodate a movement distance according to a sliding operation of the second housing.

13. The electronic device of claim 1,
wherein the electrical connection member comprises a flexible substrate,
wherein the reinforcement member is attached to opposite ends of the flexible substrate, and
wherein the connector is electrically connected to opposite ends of the flexible substrate to be supported by the reinforcement member.

14. The electronic device of claim 1, wherein the support structure is formed of a metal material.

15. An electronic device comprising:
a first housing comprising a first substrate having a receptacle disposed thereon, the receptacle comprising a first side surface and a second side surface facing each other with a terminal part interposed therebetween;
a second housing rotatably connected to the first housing through a hinge device and comprising a second substrate;
an electrical connection member comprising a connector electrically connected from the first substrate to the second substrate through the hinge device and connected to the receptacle, and a reinforcement member disposed to support the connector; and
a support structure disposed around the receptacle on the first substrate,
wherein the support structure comprises:
a first portion disposed, in the first substrate, to correspond to at least a portion of the first side surface and comprising a first tension rib; and
a second portion disposed, in the first substrate, to correspond to at least a portion of the second side surface and comprising a second tension rib, and
wherein, when the connector is connected to the receptacle, at least a portion of the reinforcement member is elastically supported by at least one of the first tension rib and the second tension rib.

16. The electronic device of claim 15,
wherein the reinforcement member comprises at least one guide hole, and
wherein, when the connector is connected to the receptacle, the reinforcement member is disposed to be supported in such a manner that at least one of the first tension rib or the second tension rib extends through the at least one guide hole.

17. The electronic device of claim 15,
wherein at least one of the first and second tension ribs comprises a first sub-tension rib and a second sub-tension rib spaced apart from the first sub-tension rib,
wherein the reinforcement member comprises at least one guide hole, and
wherein, when the connector is connected to the receptacle, the reinforcement member is disposed to be supported in such a manner that the first sub-tension rib extends through the at least one guide hole.

18. The electronic device of claim 15, wherein, when the connector is connected to the receptacle, the reinforcement member is disposed such that an edge of the reinforcement member is supported by at least one of the first and second tension ribs.

19. The electronic device of claim 15,
wherein the receptacle comprises a third side surface connecting the first side surface and the second side surface, and
wherein the support structure comprises a third portion disposed, in the first substrate, to correspond to at least a portion of the third side surface and comprising a third tension rib.

20. The electronic device of claim 19, wherein, when the connector is connected to the receptacle, the reinforcement member may be disposed to be supported by at least a portion of the third tension rib.
